(19) United States
(12) Patent Application Publication
(10) Pub. No.: US 2026/0123372 A1
(43) Pub. Date: Apr. 30, 2026

(54) MANUFACTURING SEMICONDUCTOR DEVICE USING SELECTIVE DIELECTRIC ON DIELECTRIC (DOD) DEPOSITION PROCESS

(71) Applicants: SAMSUNG ELECTRONICS CO., LTD., SUWON-SI, GYEONGGI-DO (KR); MERCK PATENT GMBH, Darmstadt (DE)

(72) Inventors: Younghun Sung, Suwon-si (KR); Guo Liu, Tempe, AZ (US); Lanxia Cheng, Tempe, AZ (US); Bhushan Zope, Tempe, AZ (US); Byungkeun Hwang, Darmstadt (DE); Sunhye Hwang, Suwon-si (KR); Youn Joung Cho, Suwon-si (KR)

(73) Assignees: SAMSUNG ELECTRONICS CO., LTD., Suwon-si (KR); MERCK PATENT GMBH, Darmstadt (DE)

(21) Appl. No.: 18/827,292

(22) Filed: Sep. 6, 2024

(51) Int. Cl. H10W 20/00; H10P 70/00

(52) U.S. Cl. CPC H10W 20/075; H10P 70/20; H10W 20/056; H10W 20/062; H10W 20/0633; H10W 20/077; H10W 20/097

(57) ABSTRACT

A method of manufacturing a semiconductor device includes providing a structure including a first insulating pattern and a metal pattern disposed on a substrate, performing a cleaning process on the structure, exposing the structure to a reducing agent, forming, selectively, a passivation layer on the metal pattern, forming, selectively, a second insulating pattern on the first insulating pattern, and performing thermal processing on the structure.

### BACKGROUND

### 1. Technical Field

The inventive concept relates to a method of manufacturing of a semiconductor device using a dielectric on dielectric (DoD) deposition process.

### 2. Discussion of Related Art

As the geometries of structures forming a semiconductor device become smaller and the types of structures continue to evolve with improvements in integration and design, improved deposition methodologies may be needed.

### SUMMARY

The inventive concept provides a method of manufacturing a semiconductor device using a dielectric on dielectric (DoD) deposition process with improved selectivity.

The inventive concept provides a method of manufacturing a semiconductor device using a DoD deposition process selectively forming an insulating pattern.

In addition, the technical idea of the inventive concept is not limited to the problems mentioned above, and the scope of the technical idea of the inventive concept may be clearly understood by those skilled in the art from the description herein.

According to an aspect of the inventive concept, there is provided method of manufacturing a semiconductor device including providing a structure including a first insulating pattern and a metal pattern disposed on a substrate, performing a cleaning process on the structure, exposing the structure to a reducing agent, forming, selectively, a passivation layer on the metal pattern, forming, selectively, a second insulating pattern on the first insulating pattern, and performing thermal processing on the structure.

According to another aspect of the inventive concept, there is provided a method of manufacturing a semiconductor device including providing a structure including a first insulating pattern and a metal pattern disposed on a substrate, performing a cleaning process on the structure, exposing the structure to a reducing agent, forming, selectively, a passivation layer on the metal pattern, forming, selectively, a second insulating pattern on the first insulating pattern, and performing thermal processing on the structure, wherein the forming of the second insulating pattern includes a plurality of cycles, each of the plurality of cycles including supplying a catalyst to the structure, wherein a first portion of the catalyst is adsorbed by the first insulating pattern, performing a first purge operation removing a second portion of catalyst, other than the first portion of the catalyst, supplying a precursor to the structure, a first portion of the precursor forming the second insulating pattern, and performing a second purge operation removing a second portion of the precursor other than the first portion of the precursor.

According to another aspect of the inventive concept, there is provided a method of manufacturing a semiconductor device including placing, in a cleaning liquid, a structure including a first insulating pattern and a metal pattern disposed on a substrate, performing a cleaning process on the structure, disposing the structure within a deposition equipment, exposing the structure to a reducing agent in a first process chamber included in the deposition equipment, forming, selectively, a passivation layer on the metal pattern in a second process chamber included in the deposition equipment different from the first process chamber, forming, selectively, a second insulating pattern on the first insulating pattern, and performing thermal processing on the structure, wherein the exposing of the structure to the reducing agent and the forming of the passivation layer on the metal pattern include disconnecting the first process chamber and the second process chamber from each other.

### BRIEF DESCRIPTION OF THE DRAWINGS

Embodiments will be more clearly understood from the following detailed description taken in conjunction with the accompanying drawings in which:

FIG. 1 is a flowchart schematically showing a method of manufacturing a semiconductor device using a dielectric on dielectric (DoD) deposition process according to some embodiments;

FIG. 2 is a plan view schematically showing deposition equipment for performing the method of manufacturing the semiconductor device using the DoD deposition process of the inventive concept according to some embodiments;

FIGS. 3 to 7, FIG. 8A, FIG. 8B, FIG. 9, and FIG. 10 are cross-sectional views, shown according to a process sequence, for explaining the method of manufacturing the semiconductor device using the DoD deposition process according to an embodiment;

FIG. 11A is a photograph of a surface of copper manufactured according to Comparative Example 1 taken by using atomic force microscopy (AFM);

FIG. 11B is a photograph of a surface of copper manufactured according to Experimental Example 1 taken by using AFM;

FIG. 12A is a photograph of a copper pattern and a SiO₂ pattern manufactured according to Comparative Example 8 taken by using transmission electron microscopy (TEM);

FIG. 12B is a photograph of a copper pattern and a SiO₂ pattern manufactured according to Comparative Example 9 taken by using TEM; and

FIG. 12C is a photograph of a copper pattern and a SiO₂ pattern manufactured according to Experimental Example 5 taken by using TEM.

### DETAILED DESCRIPTION

Hereinafter, embodiments of the inventive concept will be described in detail with reference to the attached drawings. The same reference numerals are used for the same components in the drawings, and redundant descriptions thereof may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

According to an embodiment, a dielectric on dielectric (DoD) deposition process may be a selective DoD deposition process. For example, the DoD deposition process may refer to technology that selectively deposits a subsequent insulating material on an existing insulating material.

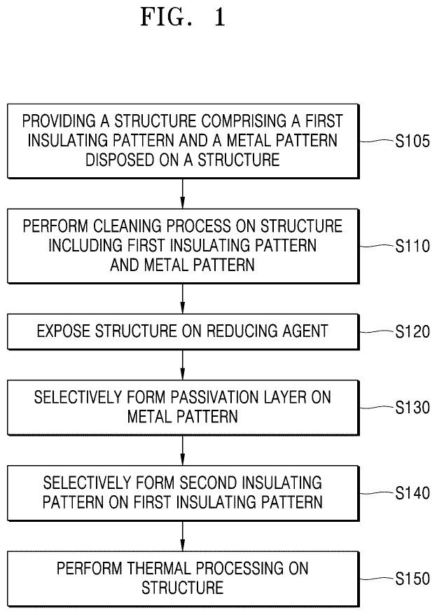

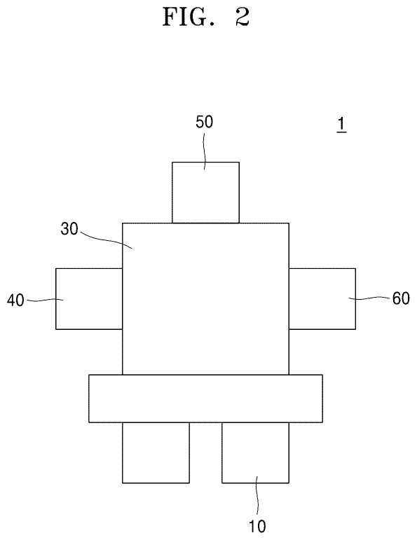

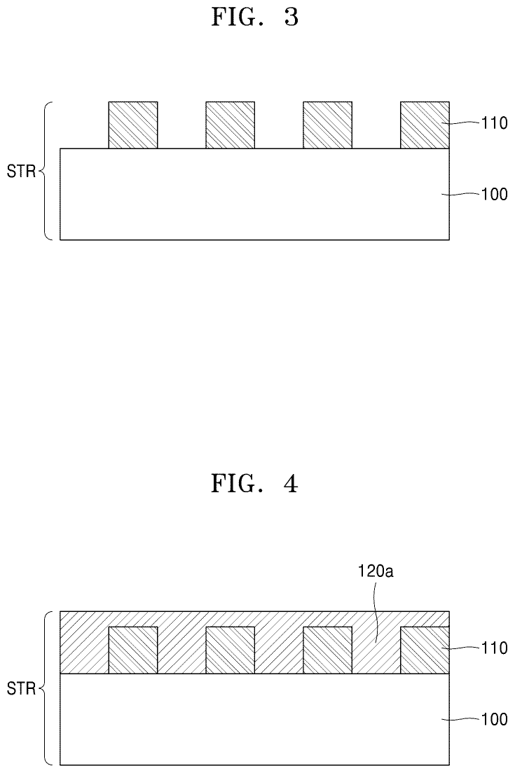

FIG. 1 is a flowchart schematically showing a method of manufacturing a semiconductor device using a dielectric on dielectric (DoD) deposition process according to some embodiments. FIG. 2 is a plan view schematically showing deposition equipment 1 for performing a method of manufacturing the semiconductor device using the DoD deposition process of the inventive concept according to some embodiments. FIGS. 3 to 7, FIG. 8A, FIG. 8B, FIG. 9, and FIG. 10 are cross-sectional views, shown according to a process sequence, for explaining a method of manufacturing the semiconductor device using the DoD deposition process according to an embodiment.

Referring to FIGS. 1 to 5, a method of manufacturing the semiconductor device using the DoD deposition process according to an embodiment may include operation S105 of providing a structure STR including a first insulating pattern 110 and a metal pattern 120 and operation S110 of performing a cleaning process on the structure STR including the first insulating pattern 110 and the metal pattern 120. The structure STR including the first insulating pattern 110 and the metal pattern 120 may be provided by various methods, and a method of forming the structure STR is not limited. The DoD deposition process may refer to a process of selectively depositing a subsequent insulating material on an insulating pattern including an existing insulating material and a metal material. For example, the existing insulating material and the metal material may form an integrated pattern with a semiconductor device, and the subsequent insulating material may be deposited on the existing insulating material and may not be deposited on the metal material. In an embodiment, the insulating material and the metal material of the insulating pattern may be disposed on a same layer. Before performing a cleaning process, a method of manufacturing the semiconductor device using the DoD deposition process may further include forming the first insulating pattern 110 and the metal pattern 120 on a substrate 100.

Referring to FIG. 3, the first insulating pattern 110 may be formed on the substrate 100. The substrate 100 may include a semiconductor material. For example, the substrate 100 may include at least one of silicon (Si), germanium (Ge), silicon-germanium (SiGe), or silicon carbide (SiC). Alternatively, the substrate 100 may include at least one of compound semiconductors such as GaAs, InAs, InGaAs, or InP. Alternatively, the substrate 100 may have a structure such as a dynamic random access memory (DRAM) cell transistor, a 3D-NAND Flash Memory, a Fin Field-Effect transistor (FinFET), a multi-bridge channel field-effect transistor (MBCFET), a capacitor, a transistor, etc. When the substrate 100 includes a structure such as DRAM, NAND FLASH, or MBCFET, the substrate 100 may include various configurations made of a single material or a plurality of materials.

Forming the first insulating pattern 110 may include forming an insulating film (not shown) on the substrate 100, forming a photo mask (not shown) on an insulating film (not shown), and performing an etching process on the insulating film (not shown) using the photo mask (not shown) as an etch mask (not shown). The first insulating pattern 110 may be formed using various methods, and embodiments are not particularly limited to examples described herein. The first insulating pattern 110 may include an insulating material. For example, the first insulating pattern 110 may include a low dielectric material. For example, the first insulating pattern 110 may include silicon oxide (SiO₂), silicon nitride (SiN), silicon oxynitride (SiON), carbon-doped silicon oxide (SiOC), carbon-doped silicon oxynitride (SiONC), aluminum oxide (Al₂O₃), or a combination thereof.

Referring to FIG. 4, a metal layer 120a covering the first insulating pattern 110 may be formed on the substrate 100. The metal layer 120a may cover an upper surface of the substrate 100. The metal layer 120a may be formed using physical vapor deposition (PVD), chemical vapor deposition (CVD), plasma enhanced CVD (PECVD), atomic layer deposition (ALD), or a combination thereof. In an embodiment, the metal layer 120a may include a metal material. For example, the metal layer 120a may include tungsten (W), titanium (Ti), aluminum (Al), molybdenum (Mo), tantalum (Ta), palladium (Pd), nickel (Ni), ruthenium (Ru), iridium (Ir), rhodium (Rh), osmium (Os), scandium (Sc), niobium (Nb), copper (Cu), platinum (Pt), silver (Ag), gold (Au), or a combination thereof. In an embodiment, the metal layer 120a may include metal nitride. The metal nitride may include, for example, tungsten nitride (WN), titanium nitride (TiN), aluminum nitride (AlN), molybdenum nitride (MoN), tantalum nitride (TaN), or a combination thereof.

In an embodiment, when the metal layer 120a includes copper (Cu), forming the metal layer 120a may include forming a seed layer (not shown) covering exposed surfaces of the substrate 100 and the first insulating pattern 110 and performing electroplating using the seed layer (not shown) as an electrode.

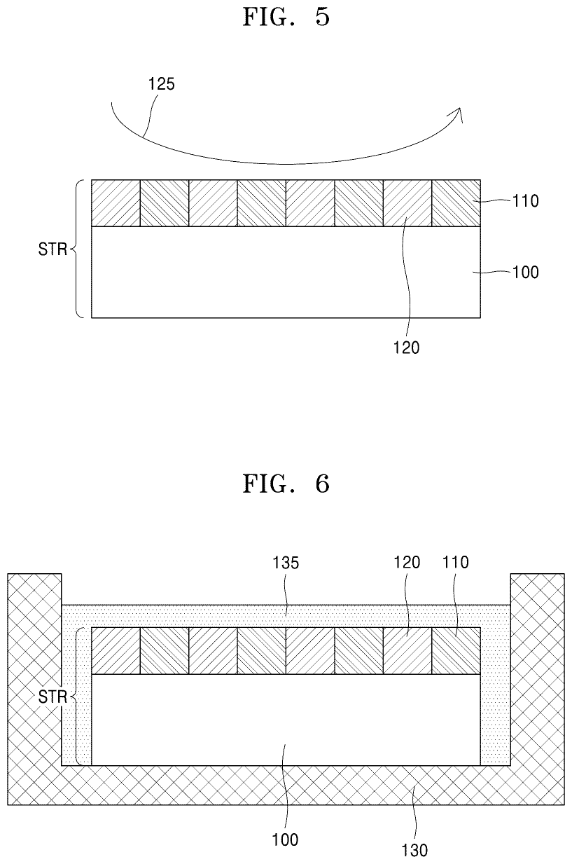

Referring to FIG. 5, a planarization process 125 may be performed on the metal layer 120a of FIG. 4. The planarization process 125 may be performed until an upper surface of the first insulating pattern 110 is exposed. The planarization process 125 may include, for example, a chemical mechanical polishing (CMP) method. Due to the planarization process 125, the metal pattern 120 may be formed from the metal layer 120a of FIG. 4. Due to the planarization process 125, the upper surface of the first insulating pattern 110 and the upper surface of the metal pattern 120 may be coplanar with each other. As a result, the structure STR including the substrate 100, the first insulating pattern 110, and the metal pattern 120 may be formed.

Referring to FIG. 1, FIG. 2, and FIG. 6, an operation S110 of performing a cleaning process on the structure STR including the first insulating pattern 110 and the metal pattern 120 may be performed. Meanwhile, a method of manufacturing the semiconductor device using the DoD deposition process may be performed in the deposition equipment 1 of FIG. 2.

The deposition equipment 1 may include an entry/exit device 10, a vacuum transfer module 30, a first process chamber 40, a second process chamber 50, and a third process chamber 60. The entry/exit device 10 may include, for example, an equipment front end module (EFEM). The entry/exit device 10 may include a load port, an atmospheric environment robot, an aligner, a fan filter unit (FFU), etc. In a case that the structure STR is disposed outside of the deposition equipment 1, the structure STR may be transferred to the vacuum transfer module 30 of the deposition equipment 1 through the load port of the entry/exit device 10. The vacuum transfer module 30 may maintain a low vacuum state, and may prevent the structure STR from being affected by external substances and/or impacts. For example, the vacuum transfer module 30 may reduce or eliminate the structure STR from being exposed to external substances and/or impacts. The first to third process chambers 40, 50, and 60 may be each connected to the vacuum transfer module 30. The first to third process chambers 40, 50, and 60 may be spaced apart from each other. The structure STR may be transferred from the vacuum transfer module 30 to a process chamber of the deposition equipment 1, for example, one of the first to third process chambers 40, 50, and 60. The structure STR may be transferred to any one of the first to third process chambers 40, 50, and 60, and a process chamber to which the structure STR is transferred and the other process chambers to which the structure STR is not transferred may be disconnected from each other. For example, when the structure STR is transferred to the first process chamber 40 and a process is performed in the first process chamber 40, the second and third process chambers 50 and 60 may not be connected to the first process chamber 40. A disconnection may be, for example, a physical disconnection of a process chamber from the vacuum transfer module 30 or a sealing of one or more of the process chamber, for example, by a door (not shown) that may seal a process chamber. After a process is performed on the structure STR in a process chamber, the structure STR may be transferred through the vacuum transfer module 30 to another process chamber in which the process has not been performed. In this case, the structure STR may be not exposed to the outside of the deposition equipment 1, and the structure STR may be protected from being affected by external substances and/or impacts. Meanwhile, in the first to third process chambers 40, 50, and 60, it should be noted that “first”, “second”, and “third” are arbitrarily numbered to distinguish a plurality of process chambers, and are not limited to the positional relationship or manufacturing sequence.

In an embodiment, operation S110 of performing a cleaning process on the structure STR including the first insulating pattern 110 and the metal pattern 120 may include exposing the structure STR to a cleaning liquid 135. As an example, exposing the structure STR to the cleaning liquid 135 may include soaking the structure STR in a container 130 containing the cleaning liquid 135. Operation S110 of performing a cleaning process on the structure STR including the first insulating pattern 110 and the metal pattern 120 may be performed in a process chamber of the deposition equipment 1, for example, one of the first to third process chambers 40, 50, and 60. For example, operation S110 of performing a cleaning process on the structure STR including the first insulating pattern 110 and the metal pattern 120 may be performed in the first process chamber 40. However, the inventive concept is not limited thereto, and operation S110 of performing a cleaning process on the structure STR including the first insulating pattern 110 and the metal pattern 120 may be performed outside the deposition equipment 1. This may vary depending on an implementation of a method of manufacturing the semiconductor device.

The cleaning liquid 135 may include, for example, an organic acid having a carboxyl group. The organic acid having the carboxyl group may include, for example,
acetic acid, citric acid, formic acid, methanoic acid, ethanoic acid, propanoic acid, butanoic acid, pentanoic acid, hexanoic acid, heptanoic acid, octanoic acid, nonanoic acid, decanoic acid, ethanedioic acid, propanedioic acid, butanedioic acid, pentanedioic acid, hexanedioc acid, heptanedioic acid, octanedioic acid, nonanedioic acid, decanedioic acid, 2-hydroxypropane-1,2,3-tricarboxylic acid, 1-hydroxypropane-1,2,3-tricarboxylic acid, prop-1-ene-1,2,3-tricarboxylic acid, propane-1,2,3-tricarboxylic acid, 2-hydroxynonadecane-1,2,3-tricarboxylic acid, benzene-1,3,5-tricarboxylic acid, or a combination thereof. In an embodiment, the cleaning liquid 135 may include diluted solutions of examples described herein.

As an example, operation S110 of performing a cleaning process on the structure STR including the first insulating pattern 110 and the metal pattern 120 may include exposing the structure STR to the cleaning liquid 135 containing citric acid of 2 wt % (percent by weight) at the room temperature for about 2 minutes and 30 seconds to about 3 minutes, and washing the structure STR with distilled water.

When a cleaning process is performed on the structure STR including the first insulating pattern 110 and the metal pattern 120, the metal oxide disposed on the upper surface of the metal pattern 120 may be removed. The metal oxide may be a by-product formed on an upper portion of the metal pattern 120 when the metal pattern 120 is exposed to external air before the structure STR is input into the deposition equipment 1. For example, the metal oxide may be a by-product formed on an upper portion of the metal pattern 120 when the metal pattern 120 is exposed to external air during the movement of the structure STR. By way of example, when the metal pattern 120 includes copper, the metal oxide may include Cu₂O or/and CuOₓ (where x is a natural number). The metal oxide may be disposed on the upper surface of the metal pattern 120 and also on the upper surface of the first insulating pattern 110. The metal oxide may be disposed on the upper surface of the metal pattern 120 and on the upper surface of the first insulating pattern 110 when the metal oxide separated from the upper surface of the metal pattern 120 is adsorbed on the upper surface of the first insulating pattern 110.

For example, washing the structure STR with distilled water may include repeatedly soaking the structure STR in distilled water for about 1 minute per wash. For example, the structure STR may be washed three times.

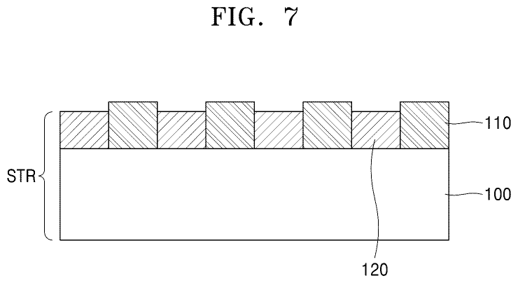

Referring to FIG. 1, FIG. 2, and FIG. 7, operation S120 of exposing the structure STR on which a cleaning process has been completed to a reducing agent may be performed. Operation S120 of exposing the structure STR to the reducing agent may be performed in process other than the first process chamber 40. For example, operation S120 of exposing the structure STR to the reducing agent may be performed in the second process chamber 50.

The reducing agent may include, for example, hydrogen-based plasma. The hydrogen-based plasma may refer to plasma generated from hydrogen or a gas group containing hydrogen and another gas (e.g., an inert gas). Alternatively, the reducing agent may include, for example, methanol, ethanol, n-propanol, isopropanol, or a combination thereof. The hydrogen-based plasma may be generated by supplying H₂ and an inert gas in a direct plasma state or a remote plasma state.

For example, when the reducing agent includes the hydrogen-based plasma, the hydrogen-based plasma may be generated by a direct plasma generation device, in an in-situ plasma generation device, or in a remote plasma generation device. For example, when the hydrogen-based plasma is generated by the direct plasma generation device, operation S120 of exposing the structure STR to the reducing agent may include supplying about 70 SCCM (flow unit) of H₂ and about 100 SCCM of Ar to the structure STR for about 3 minutes and 30 seconds to about 4 minutes and 30 seconds at a temperature range of about 250° C. (Celsius) to about 350° C. According to an embodiment, Ar may be a different type of inert gas. A pressure within the second process chamber 50 may be 1 Torr, and plasma power may be supplied to H₂ in the second process chamber 50. For example, the plasma power may be applied in a range of greater than about 0 and less than about 2000 watts (W).

When operation S120 of exposing the structure STR to the reducing agent is performed, metal oxide that may not have been removed in operation S110 of performing a cleaning process on the structure STR, or metal oxide generated during transfer between process chambers after operation S110 of performing a cleaning process on the structure STR may be removed.

During operation S120 of exposing the structure STR to the reducing agent, the height of the upper surface of the metal pattern 120 may be reduced. The height of the upper portion of the metal pattern 120 may be reduced in a case that a portion of the upper portion of the metal pattern 120 is exposed to external air and becomes a metal oxide, and the metal oxide is removed during operation S120 of exposing the structure STR to the reducing agent. The inventive concept is not limited thereto, and the height of the upper surface of the metal pattern 120 may be reduced in operation S110 of performing a cleaning process on the structure STR including the first insulating pattern 110 and the metal pattern 120 or operation S120 of exposing the structure STR to the reducing agent, or in both operations S110 and S120.

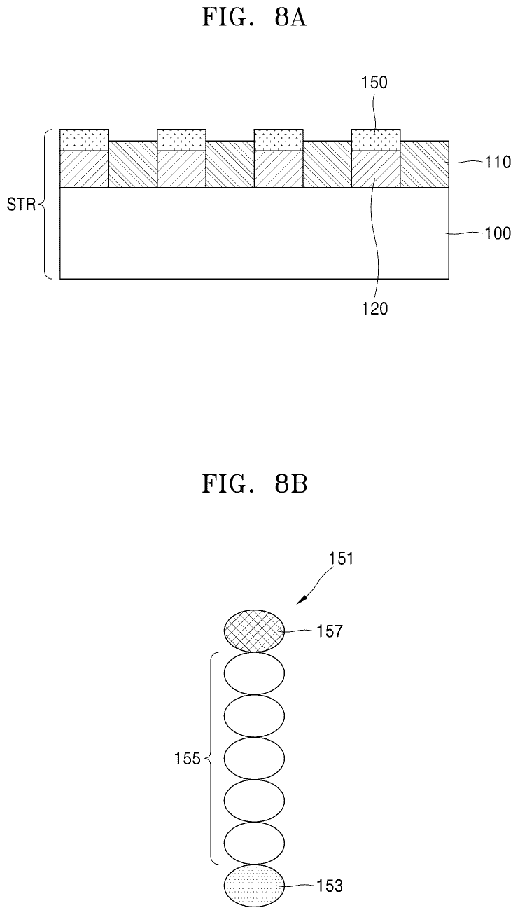

Referring to FIG. 1, FIG. 2, FIG. 8A, and FIG. 8B, operation S130 of selectively forming a passivation layer 150 on the metal pattern 120 may be performed. Before forming the passivation layer 150, an operation of lowering the temperature of the structure STR and moving the structure STR to the third process chamber 60 may be further included. That is, operation S120 of exposing the structure STR to the reducing agent and operation S130 of selectively forming the passivation layer 150 on the metal pattern 120 may be continuously performed in the deposition equipment 1. After operation S120 of exposing the structure STR to the reducing agent is performed, the structure STR may be directly transferred to the third process chamber 60 through the vacuum transfer module 30. In a case where the structure STR is directly transferred to the third process chamber 60 through the vacuum transfer module 30, the structure STR may be protected from being affected by external substances and/or impacts. Accordingly, an oxidation of the part of the upper portion of the metal pattern 120 may be reduced or prevented, and the selectivity of the passivation layer 150 formed on the metal pattern 120 may be increased. In an embodiment, the passivation layer 150 may be formed on the metal pattern 120 and may not be formed on the first insulating pattern 110. For example, the passivation layer 150 may be selectively formed on the metal pattern 120.

As an example, the passivation layer 150 may include a self-assembled monolayer (SAM) 151. FIG. 8B is an enlarged view of a molecular structure of the SAM 151. Referring to FIG. 8B, the SAM 151 may include a reactive group 153, chain groups 155, and a functional group 157. The reactive group 153 and the functional group 157 may be disposed at end portions of the chain groups 155. The reactive group 153 and the functional group 157 may be spaced apart from each other with the chain groups 155 disposed therebetween. The reactive group 153 may be a portion adsorbed to a solid surface. The SAM 151 may be adsorbed to the solid surface through the reactive group 153. The functional group 157 may be a portion that determines a function of a molecular film of the SAM 151. Depending on which molecules or atoms the functional group 157 includes, a material capable of binding to the functional group 157 may be controlled. The chain groups 155 may be portions forming a regular molecular arrangement. In the SAM 151, the chain groups 155 and the functional group 157, other than the reactive group 153, may not be adsorbed to the solid surface. The solid surface may be, for example, a metal surface. While the chain groups 155 and the functional group 157 are not adsorbed to the solid surface, the reactive group 153 may be adsorbed to the solid surface, and thus, the SAM 151 may be disposed in a direction perpendicular to the solid surface. In a case where the reactive group 153 is adsorbed to the solid surface and the SAM 151 is disposed in a direction perpendicular to the solid surface, and the SAM 151 may occupy a small area and may be adsorbed on the solid surface. When a plurality of SAMs 151 are adsorbed on the solid surface, the plurality of SAMs 151 may form a three-dimensional (3D) structure. In an embodiment, the SAM 151 may have a selective absorption for selectively forming the passivation layer 150. For example, the SAM 151 may be adsorbed only on the metal pattern 120 and may not be absorbed on the first insulating pattern 110. In an embodiment, any type of SAM 151 having a selective absorption may be used as the passivation layer 150.

As an example, operation S130 of selectively forming the passivation layer 150 on the metal pattern 120 may include exposing the structure STR to a passivation gas at a temperature of about 125° C. to about 150° C. for about 10 minutes to about 20 minutes. The pressure of the passivation gas may be about 0.13 Torr to about 0.2 Torr. The passivation gas may be supplied to the structure STR and may be decomposed or recombined with another material of the structure STR to form the passivation layer 150. The passivation gas may include, for example, methanethiol, ethanethiol, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, nonadecanethiol, tetrahydro-2H-pyran-4-thiol, 2-propene-1-thiol, tetrahydro-2H-pyran-4-thiol, thiophenol, 4-methyl-1-thiophenol, 3-methyl-1-thiophenol, 2-methyl-1-thiophenol, para-xylene-alpha-thiol, 1H,1H,2H,2H-perfluorodecanethiol, 2,2,2-trifluoroethanethiol, 4-methyl-6-trifluoromethyl-pyrimidine-2-thiol, 4-trifluoromethylbenzyl mercaptan, 4-(trifluoromethoxy)benzyl mercaptan, 4-fluorobenzyl mercaptan, 3,5-bis(trifluoromethyl)benzenethiol, 2-(trifluoromethyl)benzenethiol, 4-trifluoromethyl-2,3,5,6-tetrafluorothiophenol, 3,5-difluorobenzyl mercaptan, 4-trifluoromethyl-2,3,5,6-tetrafluorothiophenol, para-trifluoromethylbenzenethiol, di-tert-butyl disulfide, di-heptane disulfide, or a combination thereof. After exposing the structure STR to the passivation gas, a purge process may be performed on the structure STR. A purge process may be performed on the structure STR and may include supplying an inert gas such as Ar for about 15 minutes. Due to the purge process, remaining passivation gases, except for the passivation layer 150 formed on the structure STR, may be removed.

When only one of an operation S110 of performing a cleaning process on the structure STR including the first insulating pattern 110 and the metal pattern 120 or an operation S120 of exposing the structure STR to the reducing agent is performed, the metal oxide may not be removed from the upper surface of the first insulating pattern 110. In this case, the passivation gas may be adsorbed on the upper surface of the metal pattern 120 and also on the upper surface of the first insulating pattern 110, and the selectivity of the DoD deposition process may be deteriorated.

A method of manufacturing the semiconductor device according to the inventive concept may include operation S110 of performing a cleaning process on the structure STR including the first insulating pattern 110 and the metal pattern 120, and operation S120 of exposing the structure STR to the reducing agent. In a method including operation S110 of performing a cleaning process on the structure STR including the first insulating pattern 110 and the metal pattern 120 and operation S120 of exposing the structure STR to the reducing agent, the metal oxide on the upper surface of the metal pattern 120 and the metal oxide adsorbed on the upper surface of the first insulating pattern 110 may be removed. Accordingly, the passivation layer 150 may be formed on the upper surface of the metal pattern 120, and may not be formed on the first insulating pattern 110, and the selectivity of the DoD deposition process may be improved. For example, the passivation layer 150 may be formed only on the upper surface of the metal pattern 120.

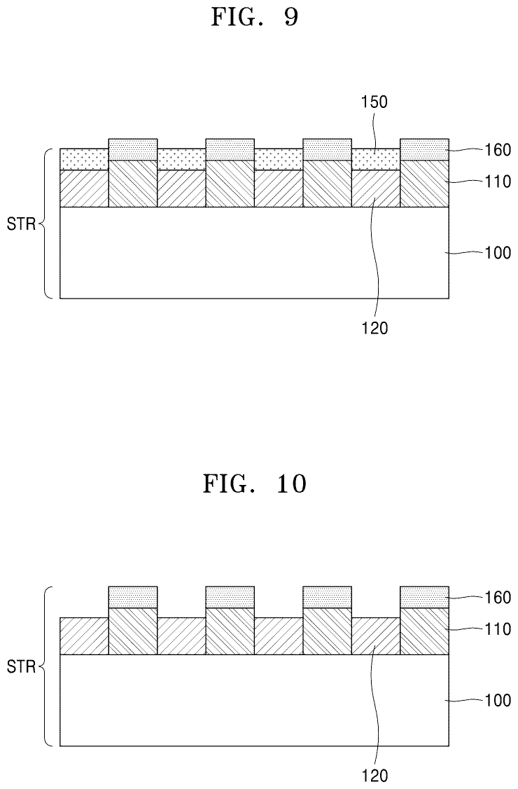

Referring to FIG. 1, FIG. 2, and FIG. 9, operation S140 of selectively forming a second insulating pattern 160 on the first insulating pattern 110 may be performed. Before forming the second insulating pattern 160, the structure STR may be transferred from the third process chamber 60. For example, the structure STR may be transferred from the third process chamber 60 to the second process chamber 50. Operation S140 of selectively forming the second insulating pattern 160 on the first insulating pattern 110 may be performed by supplying about 150 SCCM of Ar at a pressure atmosphere of about 0.7 Torr to about 0.8 Torr.

Operation S140 of selectively forming the second insulating pattern 160 on the first insulating pattern 110 may include an operation of supplying a catalyst, a first purge operation, an operation of supplying a precursor, and a second purge operation. The operation of supplying the catalyst, the first purge operation, the operation of supplying the precursor, and the second purge operation may be defined as one cycle.

The catalyst may include, for example, aluminum alkyls, aluminum dialkylamides, aluminum alkoxides, mixed alkyl-alkoxy aluminum, dialkylaluminum chlorides, trimethylaluminum (TMA), dimethylaluminum i-propoxide (DMAI), or a combination thereof. The catalyst may be supplied in pulses for about 1 second to about 2 seconds at the room temperature. The catalyst may be supplied in a single pulse or a plurality of pulses. Due to the passivation layer 150, the catalyst may be adsorbed only on the first insulating pattern 110. The catalyst may not be adsorbed to the passivation layer 150. The catalyst may promote a reaction in which the second insulating pattern 160 may be formed from the precursor.

The first purge operation may include supplying about 150 SCCM of Ar for about 25 seconds to about 35 seconds at a pressure atmosphere of about 0.7 Torr to about 0.8 Torr. The first purge operation may be performed to remove excess catalyst. The excess catalyst may be a first portion of the catalyst that may be physically adsorbed, such that the excess catalyst may not participate in the reaction. That is, the first purge operation may be performed to remove the excess catalyst other than a second portion of the catalyst used to generate the second insulating pattern 160.

The precursor may include a material capable of producing an insulating material. The precursor may include, for example, bis(tert-butoxy)(isopropoxy)silanol, bis(isopropoxy)(tert-butoxy)silanol, bis(tert-pentoxy)(isopropoxy)silanol, bis(isopropoxy)(tert-pentoxy)silanol, bis(tert-pentoxy)(tert-butoxy)silanol, bis(tert-butoxy)(tert-pentoxy)silanol, tris(tert-butoxy)silanol, tris(tert-pentoxy)silanol, or a combination thereof. The precursor may be pulsed for 30 seconds at about 105° C. to about 115° C. The precursor may be supplied in a single pulse or a plurality of pulses. The precursor may be selectively adsorbed by the first insulating pattern 110. For example, the precursor may be better adsorbed to the first insulating pattern 110 than to the passivation layer 150. After the precursor is adsorbed to the first insulating pattern 110, the second insulating pattern 160 may be formed from the precursor.

The second purge operation may include supplying about 150 SCCM of Ar for about 55 seconds to about 65 seconds at a pressure atmosphere of about 0.7 Torr to about 0.8 Torr. The second purge operation may be performed to remove an excess precursor. That is, the second purge operation may be performed to remove a first portion of the precursor that is the excess precursor other than a second portion of the precursor used to generate the second insulating pattern 160.

Operation S140 of selectively forming the second insulating pattern 160 on the first insulating pattern 110 may be repeatedly performed until the second insulating pattern 160 of a desired thickness may be formed. That is, operation S140 of selectively forming the second insulating pattern 160 on the first insulating pattern 110 may include a plurality of cycles. For example, operation S140 of selectively forming the second insulating pattern 160 on the first insulating pattern 110 may be performed two or more times. The second insulating pattern 160 may include a same material as the first insulating pattern 110.

Referring to FIG. 1, FIG. 2, and FIG. 10, operation S150 of performing thermal processing on the structure STR may be performed. Operation S150 of performing the thermal processing on the structure STR may be performed in the second process chamber 50 or the third process chamber 60, or may be performed outside the deposition equipment 1.

Operation S150 of performing the thermal processing on the structure STR may include performing rapid thermal processing (RTP). The RTP means heating thermal processing object to a high temperature within several seconds or even milliseconds. For example, a temperature increase rate of the RTP may be about 20° C./s to about 30° C./s (where s is seconds). Operation S150 of performing the thermal processing on the structure STR may include performing the thermal processing for about 25 minutes to about 35 minutes at an atmosphere of 2.6 Torr of N₂ pressure and a temperature of about 350° C. to about 400° C. Operation S150 of performing the thermal processing on the structure STR may include performing the thermal processing for about 25 minutes to about 35 minutes at a highest temperature used in the STR. While the thermal processing is performed on the structure STR, the passivation layer 150 of FIG. 9 may be removed. Accordingly, the second insulating pattern 160 may be formed only on the first insulating pattern 110 and not on the metal pattern 120. In addition, by performing the thermal processing, a dielectric constant of the second insulating pattern 160 may be lowered, a leakage current flowing into the second insulating pattern 160 may be reduced, and an electrical breakdown (EBD) voltage may be reduced. That is, the electrical characteristics of the second insulating pattern 160 may be improved by performing the thermal processing, and thus, the electrical characteristics of the entire semiconductor device may be improved.

The inventive concept will be described in more detail through comparative examples and experimental examples. However, comparative examples and experimental examples described herein are intended to illustrate the inventive concept in more detail, and the scope of the technical idea of the inventive concept is not limited by examples described herein.

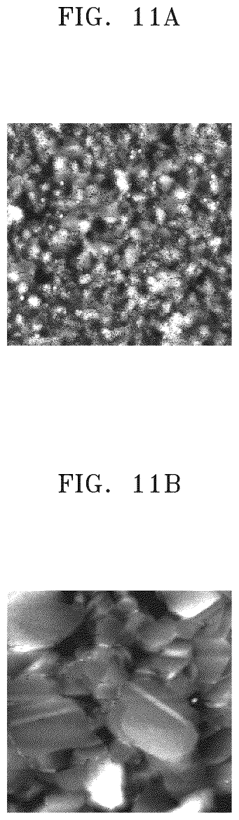

FIG. 11A is a photograph of a surface of copper manufactured according to Comparative Example 1 taken by using atomic force microscopy (AFM). FIG. 11B is a photograph of a surface of copper manufactured according to Experimental Example 1 taken by using AFM.

In Comparative Example 1, only operation (S110 in FIG. 1) of performing a cleaning process may be performed with a SiO₂ pattern and a copper pattern on a silicon wafer. Specifically, the silicon wafer may be soaked in a diluted solution of about 2 wt % citric acid at the room temperature for about 2 minutes and 45 seconds, and then washed with distilled water. At this time, the silicon wafer may correspond to the substrate 100 of FIG. 5, the SiO₂ pattern may correspond to the first insulating pattern 110 of FIG. 5, and the copper may correspond to the metal pattern 120 of FIG. 5.

In Experimental Example 1, operation S120 (in FIG. 1) of exposing the silicon wafer of Comparative Example 1 to a reducing agent may be further performed. Specifically, hydrogen-based plasma may be used as the reducing agent, and about 70 SCCM of H₂ and about 100 SCCM of Ar are supplied to the silicon wafer at a temperature of about 300° C. for about 4 minutes. At this time, the pressure may be about 1 Torr, and about 1500 W of direct plasma power is supplied to H₂ in a process chamber.

Referring to FIG. 1, FIG. 11A, and FIG. 11B, it may be seen that the crystal size of copper in Experimental Example 1 may be larger than that in Comparative Example 1. When the crystal size of copper is larger, other substances may be better adsorbed to a surface of copper. For example, when the crystal size of copper is larger, other substances may be better adsorbed to a surface of copper, the passivation layer 150 (in FIG. 8A and FIG. 9) may be better formed on the surface of copper. With the passivation layer 150 better formed on the surface of copper, the selectivity of Experimental Example 1 may be further increased in an operation of selectively forming a subsequent insulating material on SiO₂. Here, the selectivity means a ratio of the thickness of the subsequent insulating material formed on the surface of SiO₂ to the thickness of the subsequent insulating material formed on the surface of copper. The selectivity increases as the thickness of the subsequent insulating material formed on the surface of copper decreases and the thickness of the subsequent insulating material formed on the surface of SiO₂ increases.

Table 1 shows the measured thickness, dielectric constant, leakage current density, and EBD voltage of the SiO₂ film formed on the silicon wafer according to Experimental Example 2, Comparative Example 2, Comparative Example 3, Comparative Example 4, Comparative Example 5, and Comparative Example 6.

TABLE 1

| | Thickness | Dielectric | Leakage current | EBD voltage |
|---|---|---|---|---|
| | (Å) | constant (k) | density (A/cm²) | (MV/cm) |
| Experimental | 338 | 3.6 | 6.0*10⁻¹⁰ | 11.0 |
| Example 2 | | | | |
| Comparative | 352 | 5.6 | 3.0*10⁻⁸ | 10.3 |
| Example 2 | | | | |
| Comparative | 350 | 4.3 | 3.0*10⁻⁹ | 10.8 |
| Example 3 | | | | |
| Comparative | 338 | 4.9 | 3.0*10⁻⁹ | 9.0 |
| Example 4 | | | | |
| Comparative | 213 | n/a | 4.0*10⁻⁹ | 8.9 |
| Example 5 | | | | |
| Comparative | 217 | 4.0 | 3.0*10⁻⁹ | 10.0 |
| Example 6 | | | | |

In Table 1, n/a in Comparative Example 5 means that the dielectric constant value is not properly measured. The leakage current density is measured when two electrodes (+ and −) are connected to SiO₂ and a voltage of 1 MV/cm is applied to the two electrodes.

Table 2 shows the experimental conditions of Experimental Example 2, Comparative Example 2, Comparative Example 3, Comparative Example 4, Comparative Example 5, and Comparative Example 6. Experimental Example 2, Comparative Example 2, Comparative Example 3, Comparative Example 4, Comparative Example 5, and Comparative Example 6 are all applied to the experimental conditions in Table 2 with only SiO₂ on the silicon wafer.

TABLE 2

| | | Exposure to | Deposition | Subsequent |
|---|---|---|---|---|
| | Cleaning process | reducing agent | temperature (° C.) | thermal processing |
| Experimental | Same as | Same as | 150 | 400° C., N2, RTP, |
| Example 2 | Experimental | Experimental | | 30 m |
| | Example 1 | Example 1 | | |
| Comparative | Same as | Same as | 150 | — |
| Example 2 | Experimental | Experimental | | |
| | Example 1 | Example 1 | | |
| Comparative | Same as | Same as | 150 | 350° C., N2, |
| Example 3 | Experimental | Experimental | | atmospheric |
| | Example 1 | Example 1 | | pressure, 30 m |
| Comparative | Same as | — | 150 | — |
| Example 4 | Experimental | | | |
| | Example 1 | | | |
| Comparative | Same as | — | 150 | — |
| Example 5 | Experimental | | | |
| | Example 1 | | | |
| Comparative | Same as | — | 150 | 400° C., N2, RTP, |
| Example 6 | Experimental | | | 30 m |
| | Example 1 | | | |

In Table 2, being the “same as Experimental Example 1” in a cleaning process means being the same as the experimental conditions of a cleaning process used in Experimental Example 1. In addition, being the “same as Experimental Example 1” in the exposure to the reducing agent means being the same as the “experimental conditions for exposing the silicon wafer to the reducing agent” used in Experimental Example 1. In the subsequent thermal processing, in Experimental Example 2, RTP may be rapidly performed on the silicon wafer with N₂ gas at a temperature of about 400° C., and in Comparative Example 3, the thermal processing may be performed on the silicon wafer at about 2.6 Torr with N₂ gas at a temperature of 350° C., and in Comparative Example 6, RTP may be performed on the silicon wafer with N₂ gas at a temperature of about 400° C.

Referring to Experimental Example 2 and Comparative Example 2 in Tables 1 and 2, it may be confirmed that SiO₂ of Experimental Example 2 in which the subsequent thermal processing is performed may have a lower dielectric constant and leakage current density and a higher EBD voltage than SiO₂ of Comparative Examples 2 and 4 in which the subsequent thermal processing is not performed. Thus, it may be confirmed that the subsequent thermal processing improves the electrical properties of SiO₂.

Referring to Experimental Example 2 and Comparative Example 3 in Tables 1 and 2, it may be confirmed that SiO₂ of Experimental Example 2 in which the subsequent thermal processing is performed through RTP may have a lower dielectric constant and leakage current density and a higher EBD voltage than SiO₂ of Comparative Example 3 in which the subsequent thermal processing may be performed through a general thermal processing. Here, the general thermal processing is a concept in contrast to RTP and means slowly raising the temperature of thermal processing object in tens of seconds or minutes. While a subsequent thermal processing temperature of Experimental Example 2 may be about 400° C., a subsequent thermal processing temperature of Comparative Example 3 is about 350° C. Thus, it may be seen that RTP may improve the electrical properties of SiO₂ more than a general thermal processing, and that the electrical properties of SiO₂ may be further improved when a temperature range is about 400° C. A range around 400° C. may include a range of about 350° C. to about 400° C.

Referring to Experimental Example 2 and Comparative Example 6 in Tables 1 and 2, it may be confirmed that SiO₂ of Experimental Example 2 exposed to the H₂ plasma reducing agent may have a lower dielectric constant and leakage current density and a higher EBD voltage than SiO₂ of Comparative Example 6 not exposed to the reducing agent. Thus, it may be confirmed that further including the operation of exposing to the reducing agent in addition to performing a cleaning process improves the electrical properties of SiO₂.

Table 3 shows the measured concentrations (at %) of carbon, copper, oxygen, and sulfur atoms in a sample according to Experimental Example 3, Comparative Example 7, and Comparative Example 8.

TABLE 3

| | SAM | | | | | |
|---|---|---|---|---|---|---|
| | grafting | Subsequent | | | | |
| | temperature | thermal | | | | |
| | (° C.) | processing | C (at %) | Cu (at %) | O (at %) | S (at %) |
| Experimental | 150 | 400° C., N2, | 18.45 | 43.73 | 36.71 | 1.11 |
| Example 3 | | RTP, 30 m | | | | |
| Experimental | 150 | 350° C., N2, | 18.60 | 45.40 | 36.71 | 0.68 |
| Example 4 | | RTP, 30 m | | | | |
| Comparative | 150 | 150° C., no | 62.46 | 19.15 | 13.75 | 4.65 |
| Example 7 | | gas supply, | | | | |
| | | 30 m | | | | |

Experimental Example 3, Experimental Example 4, and Comparative Example 7 are the same in that the thermal processing may be performed on the sample in which the SAM 151 is grafted onto a copper layer deposited on the silicon wafer. 1-dodecanethiol (1-DDT) may be used as a material of the SAM 151, and 1-DDT is supplied for about 15 minutes at a temperature of about 125° C. to about 150° C. in the process chamber. However, Experimental Example 3, Experimental Example 4, and Comparative Example 7 are different in the thermal processing conditions as shown in Table 3.

Referring to Experimental Example 3, Experimental Example 4, and Comparative Example 7 in Table 3, it may be seen that the concentrations of carbon and sulfur atoms in the sample of Experimental Example 3 and Experimental Example 4 may be significantly lower than that of Comparative Example 7. The low concentrations of carbon and sulfur atoms in the sample mean low concentration of the SAM 151. This means that while the SAM 151 may be well removed in Experimental Examples 3 and 4, the SAM 151 may not be well removed in Comparative Example 7. That is, it may be seen that the SAM 151 may be well removed when the thermal processing temperature is in the range of about 350° C. to about 400° C.

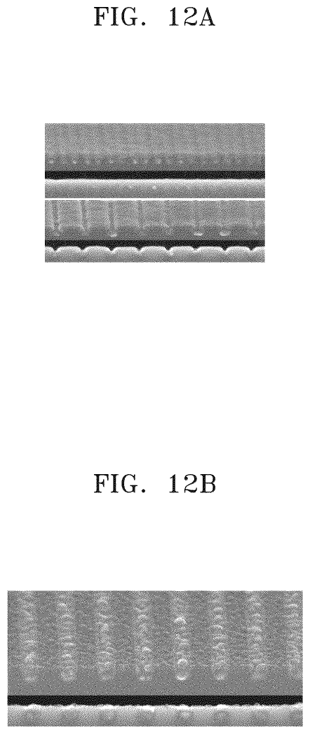

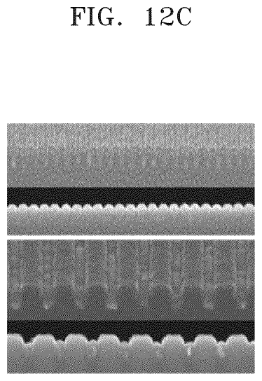

FIG. 12A is a photograph of a copper pattern and a SiO₂ pattern manufactured according to Comparative Example 8 taken by using transmission electron microscopy (TEM). FIG. 12B is a photograph of a copper pattern and a SiO₂ pattern manufactured according to Comparative Example 9 taken by using TEM. FIG. 12C is a photograph of a copper pattern and a SiO₂ pattern manufactured according to Experimental Example 5 taken by using TEM.

In Comparative Example 8, with the SiO₂ pattern and the copper pattern on the silicon wafer, operation S110 of performing a cleaning process, operation S130 of selectively forming the passivation layer 150 on the copper pattern, and operation S140 of selectively forming subsequent SiO₂ on the SiO₂ pattern may be performed. In operation S110 of performing a cleaning process, the silicon wafer may be soaked in a diluted solution of about 2 wt % citric acid at the room temperature for about 2 minutes and 45 seconds, and then washed with distilled water. Operation S130 of selectively forming the passivation layer 150 on the copper pattern may include exposing the silicon wafer to a passivation gas at a temperature of about 125° C. to about 150° C. for about 10 minutes to about 20 minutes. At this time, the pressure of the passivation gas may be about 0.13 Torr to about 0.2 Torr. The passivation gas includes 1-DDT. After the silicon wafer is exposed to the passivation gas, a purge process is performed on the silicon wafer for about 15 minutes using an inert gas such as Ar. Operation S140 of selectively forming subsequent SiO₂ on the SiO₂ pattern may include an operation of placing the silicon wafer in a process chamber and supplying a catalyst, a first purge operation, an operation of supplying a precursor, and a second purge operation. TMA may be used as the catalyst, and supplied at the room temperature for about 2 seconds. In the first purge operation, about 150 SCCM of Ar may be supplied for about 30 seconds in a pressure atmosphere of about 0.7 Torr to about 0.8 Torr. Tris(tert-pentoxy)silanol may be used as the precursor and supplied in pulses at about 110° C. for about 30 seconds. In the second purge operation, about 150 SCCM of Ar may be supplied for about 60 seconds in a pressure atmosphere of about 0.7 Torr to about 0.8 Torr.

Comparative Example 9 excludes operation S110 of performing a cleaning process in Comparative Example 8, and includes operation S120 of exposing the silicon wafer to the reducing agent. Operation S120 of exposing the silicon wafer to the reducing agent may be performed before operation S130 of selectively forming the passivation layer 150 on the copper pattern. In operation S120 of exposing the silicon wafer to the reducing agent, hydrogen-based plasma is used as the reducing agent, and about 70 SCCM of H2 and about 100 SCCM of Ar are supplied to the wafer at a temperature of about 300° C. for about 4 minutes. At this time, the pressure may be about 1 Torr, and about 1500 W of direct plasma power is supplied to H₂ in the process chamber.

Experimental Example 5 may include all of the operations of Comparative Example 8, and may include operation S120 of exposing the silicon wafer to the reducing agent after operation S110 of performing a cleaning process and before operation S130 of selectively forming the passivation layer 150 on the copper pattern. The experimental conditions of operation S120 of exposing the silicon wafer to the reducing agent of Experimental Example 5 may be the same as the experimental conditions of operation S120 of exposing the silicon wafer to the reducing agent of Comparative Example 9.

In summary, as pretreatment, in Comparative Example 8, only a cleaning process is performed, in Comparative Example 9, only an exposure to the reducing agent may be performed, and in Experimental Example 5, both a cleaning process and an exposure to the reducing agent may be performed.

Referring to FIG. 12A, in Comparative Example 8, when a pitch between the metal pattern and the SiO₂ pattern is small, it may be seen that the subsequently deposited SiO₂ may be formed on the existing SiO₂ and also on the copper pattern (see the upper photograph of FIG. 12A). Even when the pitch between the metal pattern and the SiO₂ pattern is large, it may be seen that the selectivity of the subsequently deposited SiO₂ may be limited (see the lower photograph of FIG. 12A).

Referring to FIG. 12B, it may be seen in Comparative Example 9 that the subsequently deposited SiO₂ is formed on the existing SiO₂ and also on the copper pattern. That is, it may be seen in Comparative Example 9 that there is little to no selectivity.

Referring to FIG. 12C, in Experimental Example 5, in both where the pitch between the metal pattern and the SiO₂ pattern may be small (see the upper photograph of FIG. 12A) and large (see the lower photograph of FIG. 12A), it may be confirmed that the selectivity of the subsequently deposited SiO₂ may be improved.

Referring to FIG. 12A, FIG. 12B, and FIG. 12C, when a cleaning process and an exposure to the reducing agent are performed simultaneously as in Experimental Example 5, rather than when only a cleaning process is performed as in Comparative Example 8 or only an exposure to the reducing agent is performed as in Comparative Example 9, it may be confirmed that the selectivity of the subsequently deposited SiO₂ may be improved.

While the inventive concept has been particularly shown and described with reference to embodiments thereof, it will be understood that various changes in form and details may be made therein without departing from the spirit and scope of the following claims.

What is claimed is:

1. A method of manufacturing a semiconductor device, the method comprising:
providing a structure comprising a first insulating pattern and a metal pattern disposed on a substrate;
performing a cleaning process on the structure;
exposing the structure to a reducing agent;
forming, selectively, a passivation layer on the metal pattern;
forming, selectively, a second insulating pattern on the first insulating pattern; and
performing thermal processing on the structure.

2. The method of claim 1, wherein the performing of the cleaning process comprises:
exposing the structure to a cleaning liquid including an organic acid having a carboxyl group; and
washing the structure with distilled water.

3. The method of claim 2, wherein the organic acid having a carboxyl group includes at least one of acetic acid, citric acid, formic acid, methanoic acid, ethanoic acid, propanoic acid, butanoic acid, pentanoic acid, hexanoic acid, heptanoic acid, octanoic acid, nonanoic acid, decanoic acid, ethanedioic acid, propanedioic acid, butanedioic acid, pentanedioic acid, hexanedioc acid, heptanedioic acid, octanedioic acid, nonanedioic acid, decanedioic acid, 2-hydroxypropane-1,2,3-tricarboxylic acid, 1-hydroxypropane-1,2,3-tricarboxylic acid, prop-1-ene-1,2,3-tricarboxylic acid, propane-1,2,3-tricarboxylic acid, 2-hydroxynonadecane-1,2,3-tricarboxylic acid, or benzene-1,3,5-tricarboxylic acid.

4. The method of claim 1, wherein the reducing agent includes hydrogen-based plasma.

5. The method of claim 4, wherein the exposing of the structure to the reducing agent comprises supplying H₂ and an inert gas to the structure in a temperature range of about 250° C. to about 350° C. and in a direct plasma or remote plasma state.

6. The method of claim 1, wherein the reducing agent includes at least one of methanol, ethanol, n-propanol, or isopropanol.

7. The method of claim 1, wherein the forming of the passivation layer on the metal pattern includes exposing the structure to a passivation gas, and
the passivation gas includes at least one of methanethiol, ethanethiol, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, nonadecanethiol, tetrahydro-2H-pyran-4-thiol, 2-propene-1-thiol, tetrahydro-2H-pyran-4-thiol, thiophenol, 4-methyl-1-thiophenol, 3-methyl-1-thiophenol, 2-methyl-1-thiophenol, para-xylene-alpha-thiol, 1H,1H,2H,2H-perfluorodecanethiol, 2,2,2-trifluoroethanethiol, 4-methyl-6-trifluoromethyl-pyrimidine-2-thiol, 4-trifluoromethylbenzyl mercaptan, 4-(trifluoromethoxy)benzyl mercaptan, 4-fluorobenzyl mercaptan, 3,5-bis(trifluoromethyl)benzenethiol, 2-(trifluoromethyl)benzenethiol, 4-trifluoromethyl-2,3,5,6-tetrafluorothiophenol, 3,5-difluorobenzyl mercaptan, 4-trifluoromethyl-2,3,5,6-tetrafluorothiophenol, para-trifluoromethylbenzenethiol, di-tert-butyl disulfide, or di-heptane disulfide.

8. The method of claim 1, wherein the passivation layer includes a self-assembled monolayer (SAM).

9. The method of claim 1, wherein the forming of the second insulating pattern on the first insulating pattern includes:
supplying a catalyst to the structure, wherein a first portion of the catalyst is adsorbed by the first insulating pattern;
performing a first purge operation removing a second portion of the catalyst other than the first portion of the catalyst;
supplying a precursor to the structure, wherein a first portion of the precursor forms the second insulating pattern; and
performing a second purge operation removing a second portion of the precursor other than the first portion of the precursor.

10. The method of claim 9, wherein the catalyst includes at least one of aluminum alkyls, aluminum dialkylamides, aluminum alkoxides, mixed alkyl-alkoxy aluminum, dialkylaluminum chlorides, or dimethylaluminum i-propoxide (DMAI).

11. The method of claim 9, wherein the precursor includes at least one of bis(tert-butoxy)(isopropoxy)silanol, bis(isopropoxy)(tert-butoxy)silanol, bis(tert-pentoxy)(isopropoxy)silanol, bis(isopropoxy)(tert-pentoxy)silanol, bis(tert-pentoxy)(tert-butoxy)silanol, bis(tert-butoxy)(tert-pentoxy)silanol, tris(tert-butoxy)silanol, or tris(tert-pentoxy)silanol.

12. The method of claim 1, wherein the performing of the thermal processing on the structure includes performing rapid thermal processing (RTP),
wherein a temperature increase rate of the RTP is about 20° C./s to about 30° C./s, and
the RTP is performed for about 25 minutes to about 35 minutes.

13. The method of claim 12, wherein the thermal processing on the structure is performed in a temperature range of about 350° C. to about 400° C., wherein the RTP is performed for about 25 minutes to about 35 minutes at a highest temperature used in the RTP.

14. The method of claim 1, wherein the exposing of the structure to the reducing agent and the forming of the passivation layer on the metal pattern are performed continuously in a same deposition equipment.

15. A method of manufacturing a semiconductor device, the method comprising:
providing a structure comprising a first insulating pattern and a metal pattern disposed on a substrate;
performing a cleaning process on the structure;
exposing the structure to a reducing agent;
forming, selectively, a passivation layer on the metal pattern;
forming, selectively, a second insulating pattern on the first insulating pattern; and
performing thermal processing on the structure,
wherein the forming of the second insulating pattern comprises a plurality of cycles, each of the plurality of cycles comprising:
supplying a catalyst to the structure, wherein a first portion of the catalyst is adsorbed by the first insulating pattern;
performing a first purge operation removing a second portion of catalyst, other than the first portion of the catalyst;
supplying a precursor to the structure, a first portion of the precursor forming the second insulating pattern; and
performing a second purge operation removing a second portion of the precursor other than the first portion of the precursor.

16. The method of claim 15, wherein the performing of the cleaning process on the structure comprises supplying a cleaning liquid including an organic acid having a carboxyl group.

17. The method of claim 15, wherein the reducing agent includes a hydrogen-based plasma.

18. The method of claim 15, wherein the forming of the passivation layer on the metal pattern comprises exposing the structure to a passivation gas, and
the passivation gas includes at least one of methanethiol, ethanethiol, propanethiol, butanethiol, pentanethiol, hexanethiol, heptanethiol, octanethiol, nonanethiol, decanethiol, undecanethiol, dodecanethiol, tridecanethiol, tetradecanethiol, pentadecanethiol, hexadecanethiol, heptadecanethiol, octadecanethiol, nonadecanethiol, tetrahydro-2H-pyran-4-thiol, 2-propene-1-thiol, tetrahydro-2H-pyran-4-thiol, thiophenol, 4-methyl-1-thiophenol, 3-methyl-1-thiophenol, 2-methyl-1-thiophenol, para-xylene-alpha-thiol, 1H,1H,2H,2H-perfluorodecanethiol, 2,2,2-trifluoroethanethiol, 4-methyl-6-trifluoromethyl-pyrimidine-2-thiol, 4-trifluoromethylbenzyl mercaptan, 4-(trifluoromethoxy)benzyl mercaptan, 4-fluorobenzyl mercaptan, 3,5-bis(trifluoromethyl)benzenethiol, 2-(trifluoromethyl)benzenethiol, 4-trifluoromethyl-2,3,5,6-tetrafluorothiophenol, 3,5-difluorobenzyl mercaptan, 4-trifluoromethyl-2,3,5,6-tetrafluorothiophenol, para-trifluoromethylbenzenethiol, di-tert-butyl disulfide, or di-heptane disulfide.

19. The method of claim 15, wherein the catalyst includes at least one of aluminum alkyls, aluminum dialkylamides, aluminum alkoxides, mixed alkyl-alkoxy aluminum, or dialkylaluminum chlorides, and
the precursor includes at least one of bis(tert-butoxy)(isopropoxy)silanol, bis(isopropoxy)(tert-butoxy)silanol, bis(tert-pentoxy)(isopropoxy)silanol, bis(isopropoxy)(tert-pentoxy)silanol, bis(tert-pentoxy)(tert-butoxy)silanol, bis(tert-butoxy)(tert-pentoxy)silanol, tris(tert-butoxy)silanol, or tris(tert-pentoxy)silanol.

20. A method of manufacturing a semiconductor device, the method comprising:
placing, in a cleaning liquid, a structure comprising a first insulating pattern and a metal pattern disposed on a substrate;
performing a cleaning process on the structure;
disposing the structure within a deposition equipment;
exposing the structure to a reducing agent in a first process chamber included in the deposition equipment;
forming, selectively, a passivation layer on the metal pattern in a second process chamber included in the deposition equipment different from the first process chamber;
forming, selectively, a second insulating pattern on the first insulating pattern; and
performing thermal processing on the structure,
wherein the exposing of the structure to the reducing agent and the forming of the passivation layer on the metal pattern include disconnecting the first process chamber and the second process chamber from each other.
